(19) United States
(12) Patent Application Publication
(10) Pub. No.: US 2011/0206160 A1
(43) Pub. Date: Aug. 25, 2011

(54) RECEIVING DATA COMPENSATION METHOD TO IMPROVE DATA RECEIVING RATE AND RECEIVING MODEM CIRCUIT THEREOF

(75) Inventors: HyukJun SUNG, Seongnam-si (KR); Jongpil Cho, Hwaseong-si (KR)

(73) Assignee: Samsung Electronics Co., Ltd, Suwon-si (KR)

(21) Appl. No.: 12/977,249

(22) Filed: Dec. 23, 2010

(30) Foreign Application Priority Data
Feb. 23, 2010 (KR) 2010-16275

(51) Int. Cl. H03K 9/00

(52) U.S. Cl. 375/316

(57) ABSTRACT

Included in the present general inventive concept are a receiving data compensating method to improve a data receiving rate and a receiving modem circuit thereof. The receiving data compensating method may include measuring a receiving characteristic offset based on characteristics of a receiver according to first and second state data. After measuring the receiving characteristic offset, a first data sample time offset to correspond to the first state data and a second data sample time offset to correspond to the second state data are independently decided. The decided first and second data sample time offsets are applied during compensation of receiving data received through a receiver. A near field communication (NFC) multimedia device may implement the receiving data compensation method.

### CROSS-REFERENCE TO RELATED APPLICATIONS

This U.S. non-provisional patent application claims priority under 35 U.S.C. §119 from Korean Patent Application No. 10-2010-0016275, filed on Feb. 23, 2010, the entirety of which is hereby incorporated by reference.

### BACKGROUND

1. Field of the General Inventive Concept

The present disclosure herein relates to wireless data communication and, more particularly, to a receiving data compensation method to improve a data receiving rate and a receiving modem circuit thereof.

2. Description of the Related Art

In general, near field communication (NFC) is carried out between a card and a reader. The card may be incorporated in a multimedia device, such as a mobile phone, to conduct contactless electronic payment.

There are various types of NFC protocols. Basically, the NFC protocol supports readers of ISO 14443 TYPEA and TYPEB and cards thereof. In addition, an NFC protocol supports an initiator and a target of ISO 18092 as well as a reader of ISO 15693.

Under various NFC protocols, transmission data is transmitted through a transmission channel after being source-coded in their own coding manners and a receiver of a card or a reader receives various types of transmission signals as receiving data. For example, in case of a card of ISO 14443 TYPEA, a Miller coding signal is received as receiving data. In case of a reader of ISO 14443 TYPEA, a subcarrier-load-modulated signal at a subcarrier frequency is received after being Manchester encoded or BSPK encoded. In case of a card of ISO 14443 TYPEB, an NRZ-encoded signal is received. In case of a reader of ISO 14443 TYPEB, a subcarrier-load-modulated signal at a subcarrier frequency is received after being BPSK encoded. In case of an initiator and a target of ISO 18092, a Manchester-encoded signal is received as receiving data. In case of a reader of ISO 15693, a subcarrier-load-modulated signal at a subcarrier frequency is received after being Miller encoded. A transmission rate of the receiving data ranges from 26 kbps to 847 kbps.

A data receiving error rate must be low such that a reader or a card supporting multi-protocol has improved receiving performance. However, because a high or low level duration of receiving data varies due to receiving characteristics at a receiving side of a reader or card, a data receiving error is frequently generated.

Accordingly, there is a need for techniques, devices, apparatus, etc. to reduce or minimize data receiving errors at receiving modem circuits to improve receiving performance.

### SUMMARY

Embodiments of the present general inventive concept may be achieved by providing a receiving data compensating method. In some embodiments of the present general inventive concept, the receiving data compensating method may include measuring a receiving characteristic offset based on characteristics of a receiver according to first and second state data, independently deciding a first data sample time offset to correspond to the first state data and a second data sample time offset to correspond to the second state data, and compensating receiving data by applying the first data sample time offset when the receiving data is the first state data and compensating receiving data by applying the second data sample time offset when the receiving data is the second state data.

A decision value of the first data sample time offset may be greater or smaller than that of the second data sample time offset. The decision values of the first and second data sample time offsets may be programmably variable.

The receiver may be adopted to operate at a receiving modem circuit for near field communication (NFC) and the first and second data sample time offsets may be decided according to an input offset size of a card receiving unit disposed inside the receiver.

Embodiments of the present general inventive concept may also be achieved by providing a receiving data compensating method that includes measuring a receiving characteristic offset based on characteristics of a receiver according to first and second state data before independently setting a first data sample time offset to correspond to the first state data and a second data sample time offset to correspond to the second state data, and compensating provided receiving data by applying the first and second data sample time offsets to the receiving data according to the first and second state data.

When the receiving data is first state data, the receiving data may be compensated by adding x bits (x being 2 or larger integer) to a bit number of the receiving data.

When the receiving data is second state data, the receiving data may be compensated by counting a bit number of the receiving data without addition or subtraction of the bit number of the receiving data.

When the receiving data is second state data, the receiving data may be compensated by adding x bits (x being 2 or larger integer) to a bit number of the receiving data.

When the receiving data is first state data, the receiving data may be compensated by counting a bit number of the receiving data without addition or subtraction of the bit number of the receiving data.

Setting the first and second data sample time offsets may be conducted and stored in advance during test of the receiver.

Embodiments of the present general inventive concept may also be achieved by providing a receiving modem circuit including a receiver including a card receiving unit configured to process receiving data output from a comparator and a reader receiving unit configured to process receiving data output from an analog-to-digital converter, a parameter storage configured to measure a receiving characteristic offset based on characteristics of the receiver according to first and second state data and independently store a first data sample time offset to correspond to the first state data and a second data sample time offset to correspond to the second state data, and a control processor configured to compensate the receiving data by applying the first data sample time offset when the receiving data is provided as the first state data and compensate the receiving by applying the second data sample time offset when the receiving data is provided as the second state data.

Each of the card and reader receiving units may include a bit measuring unit configured to measure one of more bit numbers of the receiving data, and decision values of the first and second data sample time offsets may be programmably set at the initial stage.

A decision value of the first data sample time offset may be greater than or equal to a decision value of the second data sample time offset.

A decision value of the first data sample time offset may be smaller than or equal to a decision value of the second data sample time offset.

The first and second data sample time offsets may be independently decided according to input offset sizes of the card receiving unit and the reader receiving unit.

Embodiments of the present general inventive concept may also be achieved by providing a near filed communication (NFC) multimedia device to implement a receiving data compensation method including an RF communication unit, an analog processing unit to receive an analog signal from the RF communication unit and covert the analog signal to a digital signal, a digital processing unit to receive the digital signal as receiving data, measure the receiving data and compensate the receiving data to overcome a receiving error therein.

The device may also include a controller to control a multimedia function of the multimedia device according to a predetermined algorithm, a universal subscriber identify module (USIM), and a single wire protocol to transfer subscriber information of the USIM to the controller when the USIM is mounted on the multimedia device.

The digital processing unit may further include a first digital circuit configured to serve as a card receiving unit to process receiving data output from a comparator of the analog processing unit, and second and third digital circuit units to serve as reader receiving units to process receiving data output from an ADC of the analog processing unit.

The digital processing unit may further include a control processor to add a first data sample time offset to a first bit number of receiving data when the receiving data is in a first state and to add a second data sample time offset different from the first data sample time offset to a second bit number of receiving data when the receiving data is in a second state.

The control processor may store initial setting decision values of the first and second data sample time offsets.

### BRIEF DESCRIPTION OF THE DRAWINGS

The present general inventive concept will become more apparent in view of the attached drawings and accompanying detailed description. The embodiments illustrated therein are provided by way of example, not by way of limitation, wherein like reference numerals refer to the same or similar elements. The drawings are not necessarily to scale, emphasis instead being placed upon illustrating aspects of the present general inventive concept.

FIG. 1 is a block diagram illustrating a receiving modem circuit according to an embodiment of the present general inventive concept.

FIG. 2 is an exemplary waveform diagram illustrating a signal received at the circuit illustrated in FIG. 1.

FIG. 3 is a timing diagram illustrating an example of receiving error generation of card receiving data when an identical offset is applied at the circuit illustrated in FIG. 1.

FIG. 4 is a timing diagram illustrating an example of receiving error generation of reader receiving data when an identical offset is applied at the circuit illustrated in FIG. 1.

FIG. 5 is a timing diagram illustrating an example of receiving error generation of card receiving data when a differential offset is applied at the circuit illustrated in FIG. 1.

FIG. 6 is a timing diagram illustrating an example of receiving error generation of reader receiving data when a differential offset is applied at the circuit illustrated in FIG. 1.

FIG. 7 is a flowchart illustrating a control flow to receive data compensation performed by the circuit illustrated in FIG. 1.

FIG. 8 is a block diagram illustrating an NFC-enabled multimedia device mounting the circuit illustrated in FIG. 1.

### DETAILED DESCRIPTION OF THE EMBODIMENTS

The features and utilities of the present general inventive concept and methods of achieving them will be apparent from the following exemplary embodiments that will be described in more detail with reference to the accompanying drawings. It should be noted, however, that the present general inventive concept is not limited to the following exemplary embodiments, and may be implemented in various forms. Accordingly, the exemplary embodiments are provided only to disclose the general inventive concept and let those skilled in the art know the category of the present general inventive concept.

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

In the specification, it will be understood that when an element is referred to as being “connected” or “coupled” to another element, it may be directly connected or coupled to the other element or intervening elements may be present.

In the drawings, the same or similar reference numerals denote the same or similar elements throughout the specification. In several drawings, connection relationships between devices and lines are merely set forth for effective description of technical aspects and other devices or circuit blocks may be further provided therebetween.

It is noted that each embodiment described and illustrated herein may include complementary embodiments.

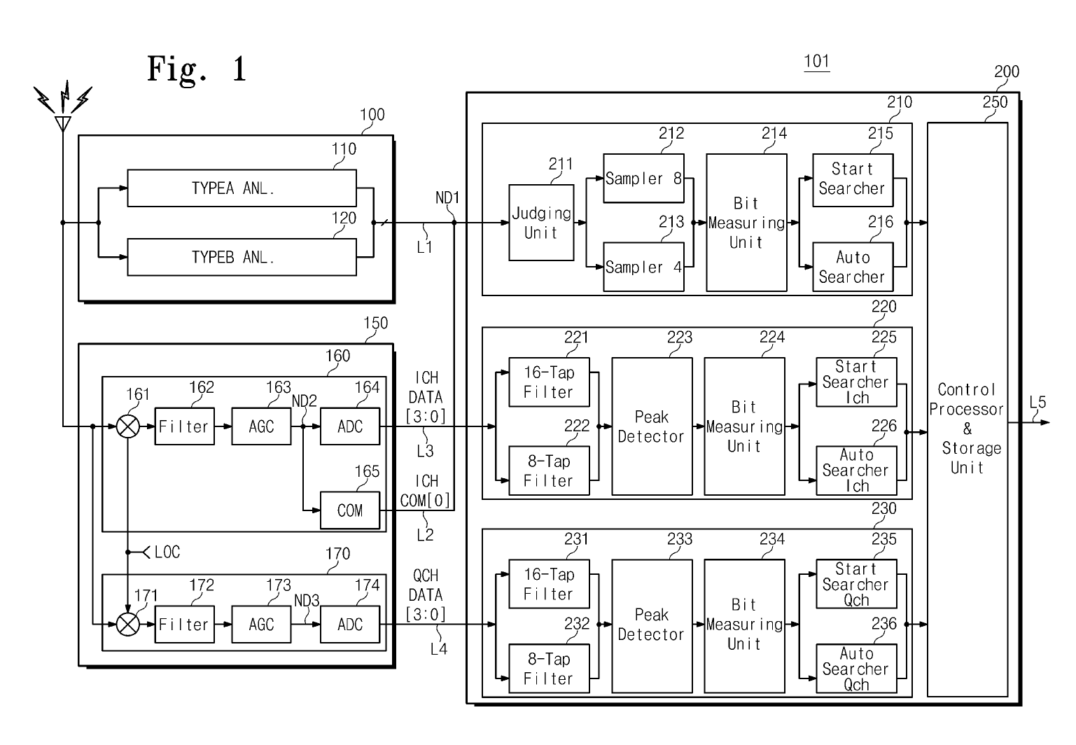

FIG. 1 is a block diagram of a receiving modem circuit according to an embodiment of the present general inventive concept.

As illustrated, the receiving modem circuit 101 may include a first analog processing unit 100, a second analog processing unit 150, and a digital processing unit 200 to receive various types of NFC protocols. The first analog processing unit 100 may include a TYPEA analog unit 110 and a TYPEB analog unit 120, and the second analog processing unit 150 may include an in-phase “I” channel analog unit 160 and a quadrature “Q” channel analog unit 170. The digital processing unit 200 may include first, second, and third digital circuit units 210, 220, and 230 and a control processor and storage unit 250.

The first analog processing unit 100 may include an analog signal processor which is capable of operating in a battery-off mode, and the second analog processing unit 150 may include an analog signal processor which operates in a battery-on mode. The I channel analog unit 160 may include a mixer 161, a filter 162, an auto gain controller (AGC) 163, an analog-to-digital converter (ADC) 164, and a comparator (COM) 165, and the Q-channel analog unit 170 may include a mixer 171, a filter 172, an AGC 173 and an ADC 174.

The first digital circuit unit 210 may include a judging unit 211, samplers 212 and 213, a bit measuring unit 214, a start searcher 215, and an auto searcher 216. The second digital circuit unit 220 may include 16-tap and 8-tap filters 221 and 222, a peak detector 223, a bit measuring unit 224, a start searcher 225, and an auto searcher 226. The third digital circuit unit 230 may include 16-tap and 8-tap filters 231 and 232, a peak detector 233, a bit measuring unit 234, a start searcher 235, and an auto searcher 236. The first digital circuit unit 210 may serve as a card receiving unit configured to process receiving data output from the comparator 165, and the second and third digital circuit units 220 and 230 may serve as reader receiving units configured to process receiving data output from the ADC 164 and from the ADC 174.

The comparator 165 may operate as an AID converter. The comparator 165 may be fed with the received signal from the antenna part and may compare the intensity of the received signal with a certain threshold value, to thereby convert a received analog signal into a binary digital signal.

The start searchers 215, 225, and 235 may be enabled in a normal mode to search a start pattern matching a protocol. The auto searchers 216, 226, and 236 may be enabled in an auto mode to search an auto pattern.

The first analog processing unit 100 may communicate with the digital processing unit 200 via one or more transmission lines L1, and through a node ND1. The I channel unit 160 of the second analog processing unit 150 may connect to the digital processing unit 200 through one or more I channel data lines L2 and L3. The Q channel unit 170 of the second analog processing unit 150 may connect to the digital processing unit 200 through one or more Q channel data lines L4.

The control processor and storage unit 250 may include storage regions to store data. The control processor and storage unit 250 may control a bit measuring unit, decode receiving data, and control overall modem operation performed by a protocol which is set according to a predetermined program. Output from the control processor and storage unit 250 may be output through one or more data lines L5.

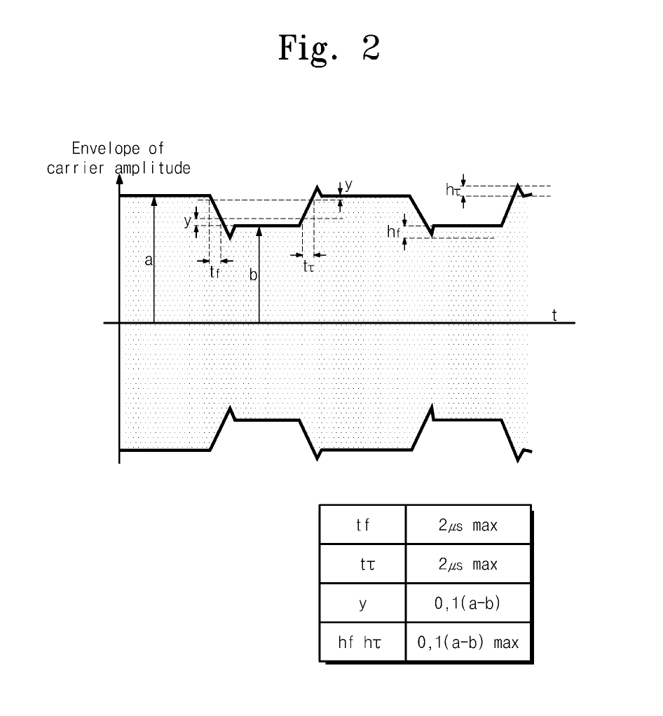

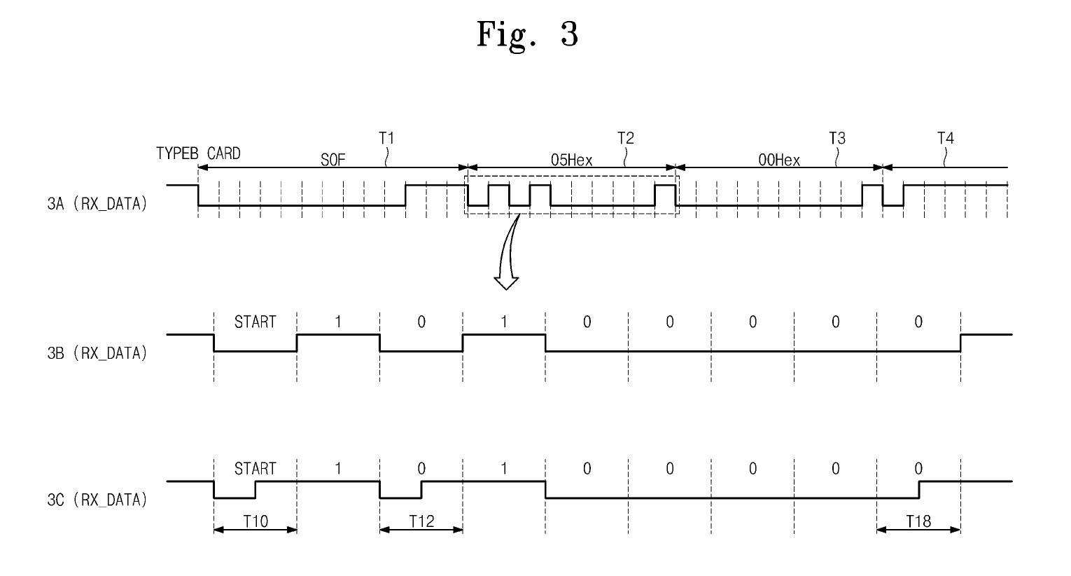

FIG. 2 illustrates an exemplary waveform diagram of a signal received at the circuit illustrated in FIG. 1. In case of a TYPEB card, a waveform of a signal received at an antenna 105 in FIG. 1 is illustrated in FIG. 2. In FIG. 2, the horizontal axis represents time and the vertical axis represents a signal amplitude. According to the waveform of the received signal, a rising slope and a falling slope vary with matching of the antenna and communication distance of a sender, and signal amplitude also varies therewith. However, a bias level of the comparator (165 in FIG. 1) is fixed. Thus, data output from the comparator 165 through line L2 and node ND1 input to the judging unit 211 of the first digital circuit unit 210 may vary for a high or low level duration to cause a receiving error, as illustrated at time periods T10 ,T12 and T18 of a waveform 3C illustrated in FIG. 3.

FIG. 3 is a timing diagram illustrating an example of receiving error generation of card receiving data when an identical offset is applied at the circuit in FIG. 1. In a TYPEB card, when receiving data (RX DATA) having high and low logic levels , as illustrated in time period T2 of waveform 3A, is normally received without an error, as illustrated in the enlarged T2 portion of waveform 3B, there is no transition within a high or low level period . However, when rising and falling slopes and signal amplitude vary with antenna matching and communication distance, there are level transitions, as illustrated at time periods T10, T12 and T18 of the waveform 3C, that cause receiving errors.

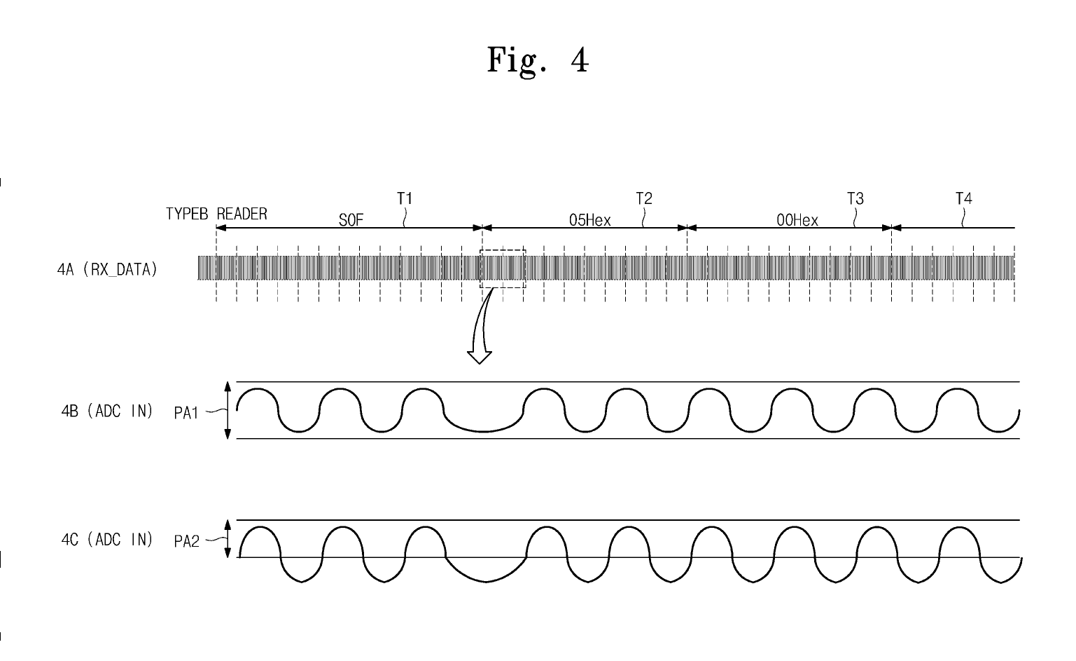

Similarly, in case of a TYPEB reader, receiving errors may also be generated as illustrated in waveform 4C of FIG. 4. More specifically, when receiving data at a node ND2 applied to the ADC (164 in FIG. 1) is saturated at an input level, a high or low level duration varies. Thus, in this case, data receiving errors may also be generated. Also, when receiving data at a node ND3 applied to the ADC (165 in FIG. 1) is saturated at an input level, a high or low level duration may vary, and data receiving errors may be generated.

FIG. 4 is a timing diagram illustrating an example of receiving error generation of reader receiving data when an identical offset is applied at the circuit illustrated in FIG. 1. In case of a TYPEB reader, when receiving data RX_DATA having high and low logic levels in a partial time period of a waveform 4A illustrated in FIG. 4A is normally received without a receiving error, receiving data having a high or low level within an input level waveform 4B illustrated in FIG. 4 is provided to a node ND2 of the ADC (164 in FIG. 1). However, when distortion is caused by receiving characteristics, there is receiving data transitioning out of an input level range PA2 as illustrated in waveform 4C. Thus, a receiving error may be generated.

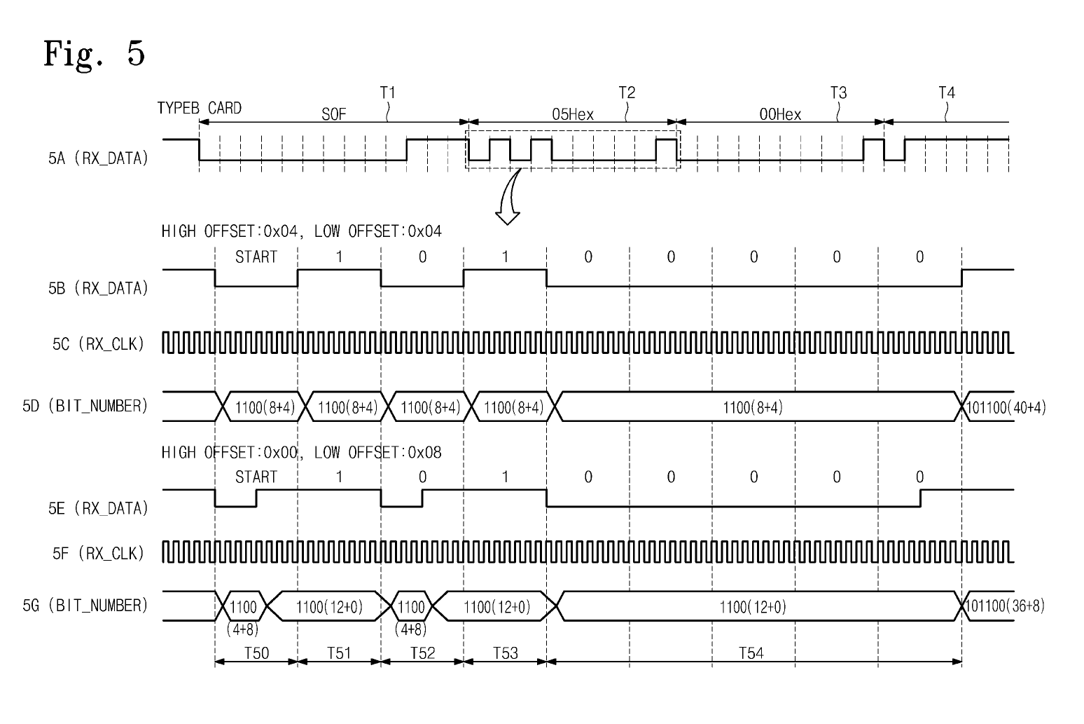

Therefore, in an embodiment of the present general inventive concept, receiving data of a card or target may be compensated as in a waveform 5G illustrated in FIG. 5 to overcome the receiving error of the waveform 3C illustrated in FIG. 3. More specifically, in the case that the receiving data is data in a first state (e.g., low), a first data sample time offset (X=8) may be added to one or more bit numbers of corresponding receiving data. In the case that the receiving data is data in a second state (e.g., high), a second data sample time offset (Y=0) may be added to one or more bit numbers of the corresponding receiving data. In these cases, decision values of the first and second data sample time offsets (X and Y) may be differently set because receiving modem circuits exhibit different receiving characteristics. The decision values of the first and second data sample time offsets (X and Y) may be stored at the initial setting of a receiving modem circuit. When the receiving characteristics are re-measured at a specific time point after the lapse of predetermined time, the decision values of the first and second data sample time offsets (X and Y) may be updated. Likewise, in the embodiment of the present general inventive concept, if low data receiving characteristics of the receiving modem circuit are relatively worse than high data receiving characteristics thereof, receiving data received as a low level is compensated, for example, to add 8 bits (to correspond to an example of the first data sample time offset) to bit numbers of original receiving data. On the other hand, if high data receiving characteristics of the receiving modem circuit are relatively worse than low data receiving characteristics thereof, receiving data received as a high level is compensated, for example, to add 0 bits (to correspond to an example of the second data sample time offset) to the bit number of original receiving data. Accordingly, a data receiving error rate is reduced to improve receiving performance.

In order to decide values of the first and second data sample time offsets (X and Y), an operation of measuring a receiving characteristic offset based on characteristics of a receiver is performed according to first and second state data through the circuit illustrated in FIG. 1 at the initial setting up of a receiving modem circuit. After the above test operation is performed, the control processor and storage unit 250 controls the bit measuring units 214, 224, and 234 to obtain compensated measuring data. If the receiving data is data in the first state, an output value obtained by adding a decision value of the second data sample time offset to a counting value of the receiving data appears at the bit measuring units 214, 224, and 234. When the bit measuring unit 214 is in an enabled state, the bit measuring units 224 and 234 may be in a disabled state. Moreover, if the bit measuring units 224 and 234 are converted to an enabled state, the bit measuring unit 214 may be in a disabled state.

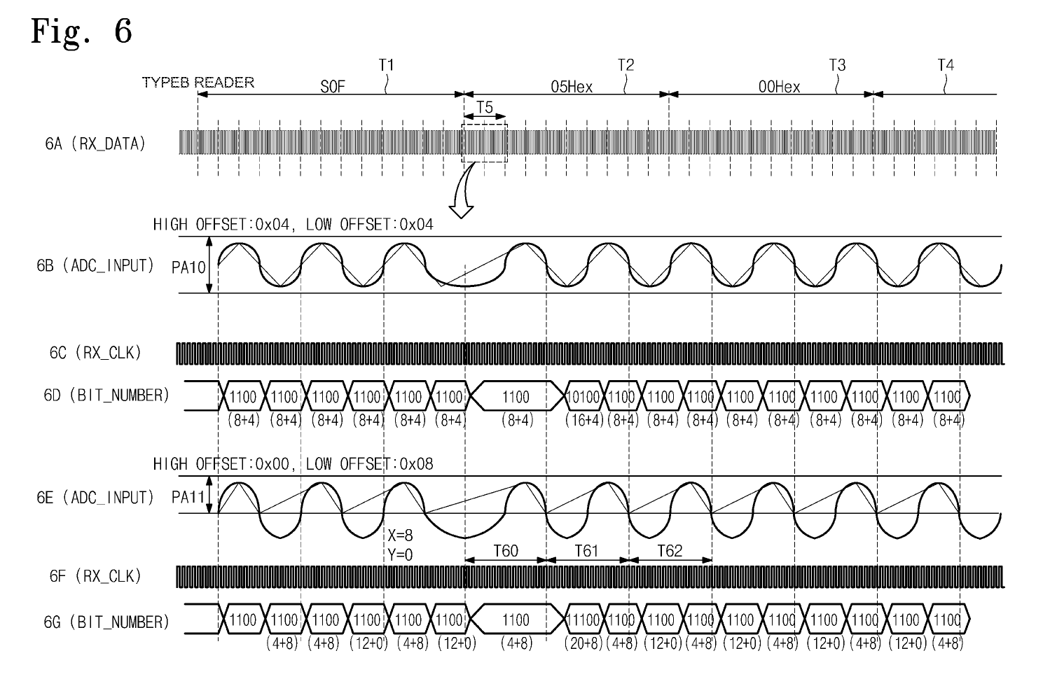

Further, in the embodiment of the present general inventive concept, receiving data of a reader is compensated as in a waveform 6G illustrated in FIG. 6 to overcome the receiving error of the waveform 4C illustrated in FIG. 4. More specifically, when the receiving data is input out of an input range PA11 and is data in the first state (e.g., low), first data sample time offset (X=8) is added to a bit number of corresponding receiving data. When receiving data is data in the second state (e.g., high), second data sample time offset (Y=0) is likewise added to a bit number of corresponding receiving data. Since data received at a time period T60 of the waveform 6G is data in the first state (e.g., low), it is added to the first data sample time offset (X=8) at a time period T61 to be compensated as “20+8=28”. In addition, since data received at the time period T61 of the waveform 6G is data in the second state (e.g., high), it is added to the second data sample time offset (Y=0) at a time period T62 to be compensated as “12+0=12”. Likewise compensation of receiving data is conducted at the next period after the receiving data is received.

Similarly, the decision values of the first and second data sample time offsets (X and Y) may be differently set because receiving modem circuits exhibit different receiving characteristics.

In the embodiment of the present general inventive concept, if low data receiving characteristics of the receiving modem circuit are relatively worse than high data receiving characteristics thereof, receiving data received as a low level may be compensated, for example, to add 8 bits (to correspond to an example of the first data sample time offset) to a bit number of original receiving data. However, it will be understood that if low data receiving characteristics of the receiving modem circuit are relatively better than high data receiving characteristics thereof, the 8 bits is added to receiving data received as high level.

FIG. 5 is a timing diagram illustrating an example of receiving error reduction of card receiving data when a differential offset is applied at the circuit illustrated in FIG. 1, and FIG. 6 is a timing diagram illustrating an example of receiving error reduction of reader receiving data when a differential offset is applied at the circuit illustrated in FIG. 1.

In FIG. 5, when receiving data RX_DATA having high and low logic levels as in time period T2 of a waveform 5A normally received without an error, there is no transition for a high or low level duration in a waveform 5B illustrated in FIG. 5. However, when rising and falling slopes and signal amplitude vary with antenna matching and communication distance, there is a level transition as illustrated at time periods T50 and T52 of a waveform 5E. In such a case, a receiving error for a data bit may be generated if a counting output like a waveform 5D is obtained using a clock waveform 5C. That is, in case of the waveform 5D, decision values of first and second data sample time offsets (X and Y) are identically set to 4 and 4 and are equivalently added to high or low level data. The lower 3 bits or 2 bits may be ignored during judgment of a bit value of the receiving data by the judging unit 211. For example, counting 8 from the receiving data and adding sample time offset 4 makes 12, which is represented by “1100” in binary notation. In this case, if the lower 3 bits “100” are discarded, “1” remains as final judgment data. As a result, because the counting output waveform 5D is obtained without consideration of data receiving characteristics of a receiving modem circuit, a receiving error rate is high and thus receiving performance is poor.

However, if a counting output waveform 5G considering differential offsets according to high and low level data is obtained as compensated receiving data, a receiving error rate is relative low and thus receiving performance is improved.

In FIG. 6, a waveform 6B is made when receiving data RX_DATA having high and low logic levels as in timing period T5 of a waveform 6A is normally received within an input level range PA10 without an error. However, when receiving data of a node ND2 applied to the ADC (164 in FIG. 1) is saturated in an input level, there is a transition out of input level range PA11 as illustrated at a waveform 6E. In this case, a receiving error is generated if a counting value waveform 6D is obtained using a clock waveform 6C.

That is, in case of the waveform 6D, decision values of first and second data sample time offsets (X and Y) are identically set to 4 and 4 and are equivalently added to high or low level data. As a result, because a counting value waveform 6D is obtained without consideration of data receiving characteristics of a receiving mode circuit, it is difficult to exhibit high receiving performance. However, as set forth above, if a counting output waveform 6G considering differential offsets according to high and low level data is obtained as compensated receiving data, a receiving error rate is relative low and thus receiving performance of a receiving mode circuit is improved.

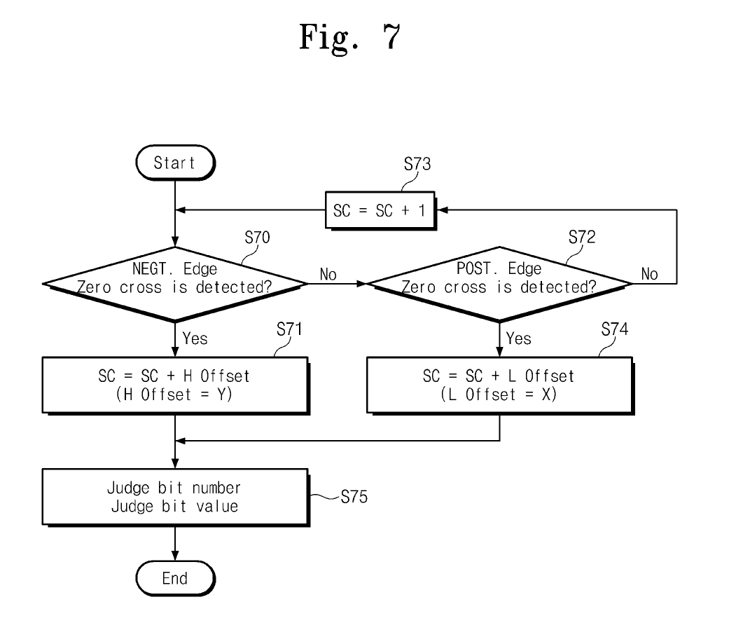

FIG. 7 is a flowchart illustrating a control flow to receive data compensation performed by the circuit illustrated in FIG. 1. The control flow may be made by controlling bit measuring units 214, 224, and 234 at the control processor and storage unit (250 in FIG. 1).

The control flow starts after measuring a receiving characteristic offset based on receiving characteristics of a receiver illustrated in FIG. 1 according to first and second state data and storing first and second data sample time offsets. In order to achieve this, the control processor and storage unit 250 acts as a parameter storage unit which independently stores the first data sample time offset to correspond to the first state data and the second data sample time offset to correspond to the second state data.

At S70, the control processor and storage unit 250 checks whether receiving data is second state data. That is, if a high-to-low transition (negative edge) is detected as in a time period T51 of a waveform 5E illustrated in FIG. 5 or zero cross is detected as in a time period T61 of a waveform 6E illustrated in FIG. 6, the receiving data is judged as the second state data, e.g., logic high data. Thus, if the receiving data is checked as the second state data at S70, the flow proceeds to S71 at which compensation is conducted to sum a sample count (SC) value of the receiving data and a high (H) offset. In the case of FIGS. 5 and 6, because a decision value Y of the second data sample time offset is zero (0), a sample count value of the receiving data is output without being changed. At S75, an output bit number and a bit value are judged. When a bit number output at a first sample count period is 4 bits, the lower 3 bits may be discarded. In addition, when the output bit number is 3 bits, the lower 2 bits may be discarded. As a result, lower bits may be discarded to obtain receiving data numbers and state values, which may also be achieved by shifting an oversampled number.

On the other hand, if the receiving data is not the second state data at S70, the flow proceeds to S72. That is, if a low-to-high transition (positive edge) is detected as in the time period T50 of the waveform 5E illustrated in FIG. 5 or zero cross is detected as in the time period T60 of the waveform 6E illustrated in FIG. 6, the receiving data may be judged as first state data, e.g., logic low data. Thus, if the receiving data is checked as the first state data at S72, the flow proceeds to S74 at which compensation is conducted to sum up a sample count (SC) value of the receiving data and a low (L) offset. In the case of FIGS. 5 and 6, because a decision value X of the first data sample time offset is 8, 8 is added to a sample count value of the receiving data before being output. If S74 is completed, the bit number and bit value output through S75 are decided.

As set forth above, when the receiving data is provided as the first state data, compensation of the receiving data is conducted by applying the first data sample time offset. When the receiving data is provided as the second state data, compensation of the receiving data is conducted by applying the second data sample time offset. Thus, a data receiving error rate is reduced.

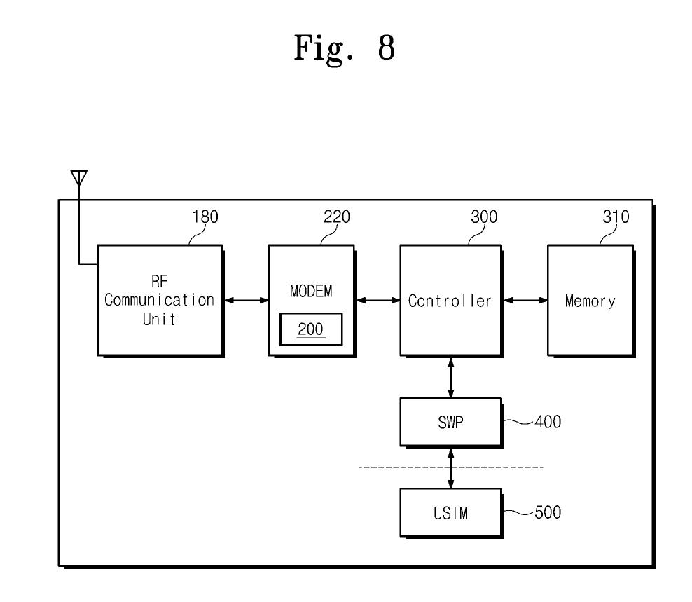

FIG. 8 is a block diagram of an NFC-enabled multimedia device mounting the circuit illustrated in FIG. 1. As illustrated, the multimedia device may include, for example, an RF communication unit 180, a modem 220 including the digital processing unit (200 in FIG. 1), a controller 300 configured to execute a main program associated with the control of a multimedia function according to a predetermined algorithm, a memory 310 configured to store a program and various types of data, a single wire protocol (SWP) 400, and a universal subscriber identity module (USIM) 500.

The SWP 400 serves as an interface to transfer subscriber information of the USIM 500 to the controller 300 when the USIM 500 is mounted on the multimedia device.

Since the modem 220 may include hardware blocks such as the digital processing unit (200 in FIG. 1), it may include a receiver unit, a parameter storage unit, and a control processor as internal circuit blocks. The receiver unit may include a card receiving unit configured to process receiving data output from a comparator and a reader receiving unit configured to process receiving data output from an analog-to-digital converter (ADC). The parameter storage unit may measure a receiving characteristic offset based on receiving characteristics of the receiver according to first and second state data and may independently store a first data sample time offset to correspond to the first state data and a second data sample time offset to correspond to the second state data. The control processor may carry out a control flow such as illustrated in FIG. 7 to compensate the receiving data. When the receiving data is provided as first state data, the control processor may compensate the receiving data by applying the first data sample time offset. When the receiving data is provided as second state data, the control processor may compensate the receiving data by applying the second data sample time offset.

Therefore, because first and second data sample time offsets are differently applied according to receivers, the multimedia device illustrated in FIG. 8 may have a high data receiving rate.

As set forth above, because first and second data sample time offsets are differently applied according to receivers during compensation of receiving data, a data receiving error rate is reduced to improve data receiving performance.

Although embodiments of the present general inventive concept have been described with respect to an NFC receiver, it will be understood that the present general inventive concept is not limited thereto and may be applied to other communication systems.

While the present general inventive concept has been described with reference to exemplary embodiments, it will be apparent to those skilled in the art that various changes and modifications may be made without departing from the spirit and scope of the present general inventive concept. Therefore, it should be understood that the above embodiments are not limiting, but illustrative. Thus, the scope of the present general inventive concept is to be determined by the broadest permissible interpretation of the following claims and their equivalents, and shall not be restricted or limited by the foregoing description.

Although a few embodiments of the present general inventive concept have been shown and described, it would be appreciated by those skilled in the art that changes may be made in these embodiments without departing from the principles and spirit of the general inventive concept, the scope of which is defined in the claims and their equivalents.

What is claimed is:

1. A receiving data compensating method comprising:
measuring a receiving characteristic offset based on characteristics of a receiver according to first and second state data;
independently deciding a first data sample time offset to correspond to the first state data and a second data sample time offset to correspond to the second state data; and
compensating receiving data by applying the first data sample time offset when the receiving data is the first state data and compensating receiving data by applying the second data sample time offset when the receiving data is the second state data.

2. The receiving data compensating method of claim 1, wherein a decision value of the first data sample time offset is greater than that of the second data sample time offset.

3. The receiving data compensating method of claim 1, wherein a decision value of the second data sample time offset is smaller than that of the second data sample time offset.

4. The receiving data compensating method of claim 1, wherein decision values of the first and second data sample time offsets are programmably variable.

5. The receiving data compensating method of claim 1, wherein the receiver is adopted to operate at a receiving modem circuit for near field communication (NFC)

6. The receiving data compensating method of claim 1, wherein the first and second data sample time offsets are decided according to an input offset size of a card receiving unit disposed inside the receiver.

7. The receiving data compensating method of claim 1, wherein the first and second data sample time offsets are decided according to an input offset size of a reader receiving unit disposed inside the receiver.

8. A receiving modem circuit comprising:
a receiver including a card receiving unit configured to process receiving data output from a comparator and a reader receiving unit configured to process receiving data output from an analog-to-digital converter;
a parameter storage unit configured to measure a receiving characteristic offset based on characteristics of the receiver according to first and second state data and independently store a first data sample time offset to correspond to the first state data and a second data sample time offset to correspond to the second state data; and
a control processor configured to compensate the receiving data by applying the first data sample time offset when the receiving data is provided as the first state data and to compensate the receiving data by applying the second data sample time offset when the receiving data is provided as the second state data.

9. The receiving modem circuit of claim 8, wherein the card receiving unit includes a bit measuring unit configured to measure one or more bit numbers of the receiving data.

10. The receiving modem circuit of claim 8, wherein the reader receiving unit includes a bit measuring unit configured to measure one or more bit numbers of the receiving data.

11. The receiving modem circuit of claim 8, wherein decision values of the first and second data sample time offsets are programmably set at the initial stage.

12. The receiving modem circuit of claim 8, wherein a decision value of the first data sample time offset is greater than or equal to a decision value of the second data sample time offset.

13. The receiving modem circuit of claim 8, wherein a decision value of the first data sample time offset is smaller than or equal to a decision value of the second data sample time offset.

14. The receiving modem circuit of claim 8, wherein the first and second data sample time offsets are independently decided according to input offset sizes of the card receiving unit and the reader receiving unit.

15. A receiving data compensating method comprising:
measuring a receiving characteristic offset based on characteristics of a receiver according to first and second state data before independently setting a first data sample time offset to correspond to the first state data and a second data sample time offset to correspond to the second state data; and
compensating receiving data by applying the first and second data sample time offsets to the receiving data according to the first and second state data.

16. The receiving data compensating method of claim 15, wherein when the receiving data is first state data, the receiving data is compensated by adding x bits (x being 2 or larger integer) to a bit number of the receiving data.

17. The receiving data compensating method of claim 16, wherein when the receiving data is second state data, the receiving data is compensated by counting the bit number of the receiving data without addition or subtraction of the bit number of the receiving data.

18. The receiving data compensating method of claim 15, wherein when the receiving data is second state data, the receiving data is compensated by adding x bits (x being 2 or larger integer) to the bit number of the receiving data.

19. The receiving data compensating method of claim 18, wherein when the receiving data is first state data, the receiving data is compensated by counting the bit number of the receiving data without addition or subtraction of the bit number of the receiving data.

20. The receiving data compensating method of claim 15, wherein setting the first and second data sample time offsets is conducted and stored in advance during test of the receiver.

21. A near field communication (NFC) multimedia device to implement a receiving data compensation method, comprising:
an RF communication unit;
an analog processing unit to receive an analog signal from the RF communication unit and convert the analog signals to a digital signal; and
a digital processing unit to receive the digital signal as receiving data, measure the receiving data and compensate the receiving data to overcome a receiving error therein.

22. The device of claim 21, further comprising:
a controller to control a multimedia function of the multimedia device according to a predetermined algorithm;
a universal subscriber identity module (USIM); and
a single wire protocol (SWP) to transfer subscriber information of the USIM to the controller when the USIM is mounted on the multimedia device.

23. The device of claim 21, wherein the digital processing unit further comprises:
a first digital circuit configured to serve as a card receiving unit to process receiving data output from a comparator of the analog processing unit; and
second and third digital circuit units to serve as reader receiving units to process receiving data output from an ADC of the analog processing unit.

24. The device of claim 21, wherein the digital processing unit further comprises:
a control processor to add a first data sample time offset to a first bit number of receiving data when the receiving data is in a first state and to add a second data sample time offset different from the first data sample time offset to a second bit number of receiving data when the receiving data is in a second state.

25. The device of claim 24, wherein the control processor stores initial setting decision values of the first and second data sample time offsets.
